(19) United States
(12) Patent Application Publication
(10) Pub. No.: US 2016/0005960 A1
(43) Pub. Date: Jan. 7, 2016

(54) FILM FORMATION METHOD AND NONVOLATILE MEMORY DEVICE

(71) Applicant: Kabushiki Kaisha Toshiba, Tokyo (JP)

(72) Inventor: Kyoichi SUGURO, Kanagawa-ken (JP)

(21) Appl. No.: 14/857,213

(22) Filed: Sep. 17, 2015

Related U.S. Application Data
(62) Division of application No. 14/003,981, filed on Nov. 11, 2013.

(30) Foreign Application Priority Data
Mar. 25, 2011 (JP) 2011-067632

(51) Int. Cl. H01L 43/12; H01L 43/10; H01L 43/02; H01L 43/08

(52) U.S. Cl. CPC H01L 43/12; H01L 43/08; H01L 43/10; H01L 43/02

(57) ABSTRACT

According to one embodiment, a film formation method can include irradiating a layer to be processed provided on an underlayer with an ionized gas cluster containing any one of oxygen and nitrogen to modify at least part of the layer.

### FIELD

Embodiments described herein relate generally to a film formation method and a nonvolatile memory device.

### BACKGROUND

Large scale integration circuits (LSIs) in which transistors, resistances, electric circuits, and the like are integrated on one chip are widely used these days in important portions of computers, communication devices, etc. Hence, the performance of computers, communication devices, etc. depends in part on the LSI performance. Means for improving the performance of the LSI include increasing the integration degree thereof. To increase the integration degree of the LSI, it is necessary to downsize elements. In the case of, for example, a MOS field effect transistor, the downsizing of the element can be achieved by shortening the gate length of the MOS, thinning the source/drain region, and the like. Furthermore, with the progress of the downsizing of elements, also coatings, stacked films, electrode films, and the like included in the elements are required to have higher quality.

### CITATION LIST

### Patent Literature

PTL 1
JP-A 2009-117673

### BRIEF DESCRIPTION OF DRAWINGS

FIGS. 1A and 1B are schematic film cross-sectional views for describing a film formation method according to a first embodiment;

FIG. 2 is a schematic cross-sectional view for describing an overview of a film formation apparatus according to the first embodiment;

FIGS. 3A to 3C are schematic cross-sectional views for describing specific examples of the element;

FIGS. 4A and 4B are schematic film cross-sectional views for describing a film formation method according to a second embodiment;

FIGS. 5A and 5B are schematic film cross-sectional views for describing a modification example of the film formation method according to the second embodiment;

FIGS. 6A to 6D are schematic film cross-sectional views for describing another modification example of the film formation method according to the second embodiment;

FIGS. 7A and 7B are schematic film cross-sectional views for describing a film formation method according to a third embodiment;

FIGS. BA to 8C are views for describing examples in which a side wall deposition film is formed on the side surface of the layer to be processed after processing;

FIGS. 9A and 9B are schematic film cross-sectional views for describing a film formation method according to a fourth embodiment; and

FIG. 10 is an element cross-sectional view according to a fifth embodiment.

### DETAILED DESCRIPTION

In general, according to one embodiment, a film formation method is disclosed. The method can include irradiating a layer to be processed provided on an underlayer with an ionized gas cluster containing any one of oxygen and nitrogen to modify at least part of the layer.

Hereinbelow, embodiments are described with reference to the drawings. In the following description, identical components are marked with the same reference numerals, and a description of components once described is omitted as appropriate. For example, a layer (or a film) included in a nonvolatile memory device can be modified or processed by methods according to embodiments.

### First Embodiment

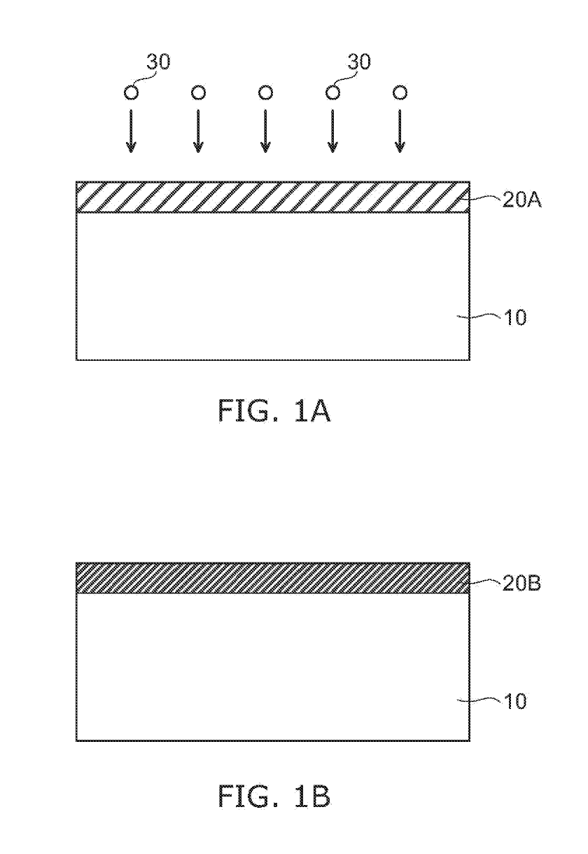

FIGS. 1A and 1B are schematic film cross-sectional views for describing a film formation method according to a first embodiment.

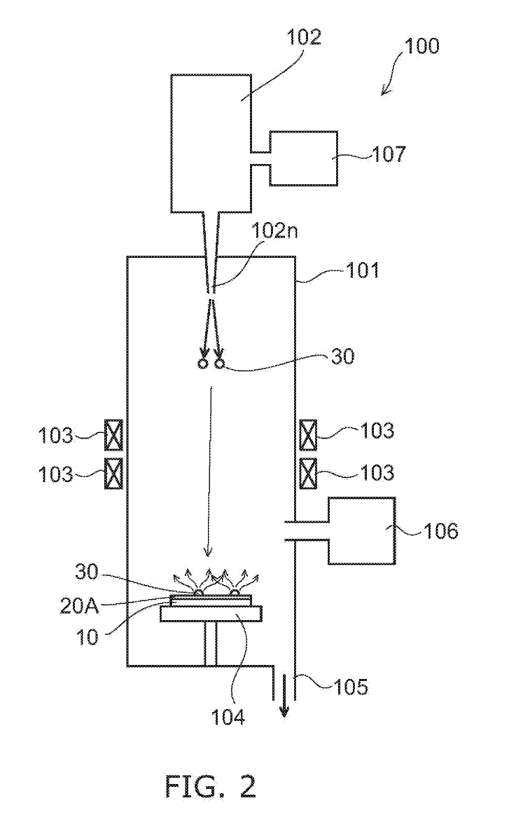

FIG. 2 is a schematic cross-sectional view for describing an overview of a film formation apparatus according to the first embodiment.

In the film formation method according to the first embodiment, as shown in FIG. 1A, the surface of a metal oxide film 20A provided on an underlayer 10 is irradiated with gas cluster ions (ionized gas cluster) 30 containing oxygen. As shown in FIG. 1B, the density of a metal oxide film 20B after the irradiation with the gas cluster ions 30 is made higher than the density of the metal oxide film 20A before the irradiation with the gas cluster ions 30. The underlayer 10 is a semiconductor layer, metal layer, insulating layer, magnetic layer, or the like.

The film formation method shown in FIG. 1 is performed by a film formation apparatus 100 shown in FIG. 2.

The film formation apparatus 100 shown in FIG. 2 includes a vacuum chamber 101, a gas pressurization mechanism 102, an acceleration mechanism 103, and a substrate support stand 104. The gas pressurization mechanism 102 is connected to the vacuum chamber 101. The gas pressurization mechanism 102 protrudes its nozzle portion 102n into the vacuum chamber 101. The end of the nozzle portion 102n opens with a diameter of approximately 0.5 mm to 2 mm. In the numerical value range of the embodiment, the expression of “0.5 mm to 2 mm” means not less than 0.5 mm and not more than 2 mm.

The film formation apparatus 100 further includes gas supply mechanisms 106 and 107. The gas supply mechanism 106 is filled with, for example, an inert gas such as argon (Ar). A valve that controls the gas supply from the gas supply mechanism 106 to the vacuum chamber 101 is provided between the gas supply mechanism 106 and the vacuum chamber 101. The use of the gas supply mechanism 107 is described later.

The atmosphere in the vacuum chamber 101 is discharged via an exhaust port 105. The reduced pressure atmosphere in the vacuum chamber 101 is kept at, for example, about 1×10⁻⁵ Pa. (Here, “×” means multiplication sign.) The gas pressurization mechanism 102 is filled with oxygen (O) or a gas of oxygen with an inert gas such as argon (Ar) and helium (He) added. The gas put in the gas pressurization mechanism 102 is pressurized at not less than 5 atmospheres and less than 10 atmospheres.

A silicon substrate as an example of the underlayer 10 is mounted on the substrate support stand 104. The metal oxide film 20A is provided on the underlayer 10. The material of the metal oxide film 20A is aluminum oxide (Al₂O₃), lanthanum oxide (La₂O₃), lanthanum aluminum oxide (LaAlO), hafnium oxide (HfO₂), cerium oxide (CeO₂), magnesium oxide (MgO), or the like.

When the gas pressurized in the gas pressurization mechanism 102 at not less than 5 atmospheres and less than 10 atmospheres is discharged into the vacuum chamber 101 via the fine nozzle portion 102n, the gas expands adiabatically near the end of the nozzle portion 102n. Consequently, the gas is cooled in the vacuum chamber 101 to generate a gas cluster. Furthermore, in the film formation apparatus 100, the gas cluster is irradiated with electrons of 30 eV or less. Thereby, electrons collide with the gas cluster, and an outermost-shell electron of an atom in the cluster is excited to be released from the cluster. Thus, a gas cluster ion 30 having a positive charge with a valence of about one to several is generated in the gas cluster. That is, the gas cluster refers to an aggregate of at least either of molecules and atoms in a gaseous state. In other words, one of an aggregate of a plurality of molecules, an aggregate of a plurality of atoms, and an aggregate of one or more molecules and one or more atoms in a gaseous state is referred to as the gas cluster. An ionized gas cluster refers to a gas cluster in which at least about one to several of the molecules and the atoms are ionized.

The number of atoms contained in the gas cluster ions 30 is not less than 100 and not more than 20,000. The number of atoms contained in the gas cluster ions 30 is preferably not less than 100 and not more than 10,000, more preferably not less than 100 and not more than 3,000.

The following method is used to make the number of atoms contained in the gas cluster ions 30 not more than 20,000, not more than 10,000, or not more than 3,000. For example, gas cluster ions 30 of a relatively large number of atoms (for example, the number of atoms being not more than 10,000) are collided with argon (Ar) supplied from the gas supply mechanism 106 into the vacuum chamber 101, and by the collision, the gas cluster ions 30 are divided into smaller pieces. Thereby, a gas cluster of a smaller number of atoms is formed. For example, gas cluster ions 30 containing 2,000 or more and 5,000 or less atoms are accelerated with 30 V to 60 kV, and then collided with neutral gas molecules of argon (Ar) or the like. Thus, gas cluster ions 30 containing a smaller number of atoms are formed.

The gas cluster ions 30 are accelerated in the film formation apparatus 100 by the acceleration mechanism 103 in the direction from the nozzle portion 102n to the substrate support stand 104. By the acceleration, the kinetic energy per atom in the gas cluster ions 30 immediately before the gas cluster ions 30 are applied to the underlayer 10 becomes 15 eV or less. The kinetic energy per atom in the gas cluster ions 30 immediately before the gas cluster ions 30 are applied to the underlayer 10 is preferably 12 eV or less.

In other words, through the acceleration of the gas cluster ions 30 in the film formation apparatus 100, the energy per atom in the gas cluster ions 30 becomes 15 eV or less, preferably 12 eV or less.

In the first embodiment, the surface of the metal oxide film 20A is irradiated with gas cluster ions 30 containing 3,000 or more and 10,000 or less oxygen atoms having such a kinetic energy at a level not less than 1×10¹⁴ (/cm²) and not more than 5×10¹⁵ (/cm²) in number. Such irradiation of the surface of the metal oxide film 20A provides a metal oxide film 20B that is stoichiometric or has a slightly higher level of oxygen than the stoichiometric composition, which is further oxidized than the metal oxide film 20A with a lower level of oxygen than the stoichiometric composition. As a result, the density of the metal oxide film 20B after the irradiation with the gas cluster ions 30 is higher than the density of the metal oxide film 20A before the irradiation with the gas cluster ions 30.

A metal oxide film of aluminum oxide (Al₂O₃), lanthanum oxide (La₂O₃), lanthanum aluminum oxide (LaAlO), hafnium oxide (HfO₂), cerium oxide (CeO₂), magnesium oxide (MgO), or the like can be formed also by the sputtering method. For example, the reactive sputtering method uses a metal target or an alloy target and performs a DC discharge of a mixed gas of oxygen and argon to form a sputtering film (a metal oxide film) on an underlayer. Furthermore, the RF sputtering method uses a metal oxide target and performs an RF discharge of argon or an oxygen-containing argon gas to form a sputtering film (a metal oxide film) on an underlayer.

However, the sputtering method cannot provide a metal oxide film with a sufficient density because the mobility of sputter atoms to adhere onto the underlayer is not so large as in the embodiment. For example, assuming that the density of a bulk crystal of aluminum oxide (Al₂O₃), lanthanum oxide (La₂O₃), lanthanum aluminum oxide (LaAlO), hafnium oxide (HfO₂), cerium oxide (CeO₂), magnesium oxide (MgO), or the like is “1” in value of standard, the density of the metal film formed by sputtering has an upper limit of “0.90 to 0.95” in value of standard. One of the factors in the fact that the density of the metal oxide film thus has an upper limit of approximately “0.90 to 0.95” in value of standard is an oxygen deficiency in the metal oxide film.

The metal oxide film formed by the sputtering method may have a fixed charge density of 1×10¹¹ cm⁻² or more. Therefore, if such a metal oxide film is used as a gate oxide film, the threshold voltage may become unstable or the reliability may be degraded.

On the other hand, ALD (atomic layer deposition) or CVD (chemical vapor deposition) can form a metal oxide film. However, in these methods, the precursor molecule may contain a halogen component (F, Cl, I, etc.) or an organic component (CH₄). Consequently, these components may be taken into the metal oxide film. Therefore, the film quality is determined by the degree to which the halogen component or the organic component can be removed by heat treatment.

It is difficult to remove a halogen component or an organic component from a metal oxide film containing the component by ordinary lamp heating or electric furnace heating, for example. Furthermore, ALD or CVD causes a high fixed charge density as in the case of forming by the sputtering method. Therefore, an instability in the threshold voltage, a degradation in reliability, and the like are caused. Although a method in which oxidation is promoted in an ozone atmosphere while UV irradiation is performed may also be possible, a sufficient film density is not obtained so far.

In contrast, it has been found that the density of the metal oxide film 20B fabricated by the embodiment is “0.95 to 1” in value of standard. This is because of the following.

For example, if the metal oxide film 20A is irradiated with gas cluster ions 30 containing oxygen atoms, the temperature of the surface of the metal oxide film 20A irradiated with the gas cluster ions 30 (a portion of the surface of the metal oxide film 20A with a diameter approximately equal to that of the gas cluster ions 30) increases locally to approximately 10,000 degrees C. in a picosecond (10⁻¹² second). In addition, the local portion of the surface receives the kinetic energy of the gas cluster ions 30.

Therefore, in the film formation according to the embodiment, the oxidation reaction of the metal oxide film 20A and the migration of atoms in the metal oxide film 20A (a phenomenon in which components in the metal oxide film move on the underlayer 10) are promoted. Thus, the embodiment can provide a compact (dense) metal oxide film 20B with a low fixed charge density as compared to the cases of using the sputtering method, ALD, and CVD.

The amount of the decrease in the Gibbs free energy when a metal film of aluminum (Al), lanthanum (La), hafnium (Hf), cerium (Ce), or the like changes into a metal oxide film is larger than the amount of the decrease in the Gibbs free energy when silicon (Si) changes into silicon oxide (SiO₂). Thus, the film formation method of the embodiment is effective when the metal oxide film 20A, which is more thermally stable than silicon oxide (SiO₂), is modified.

Next, elements in which modifying a metal oxide film like the embodiment is effective are described.

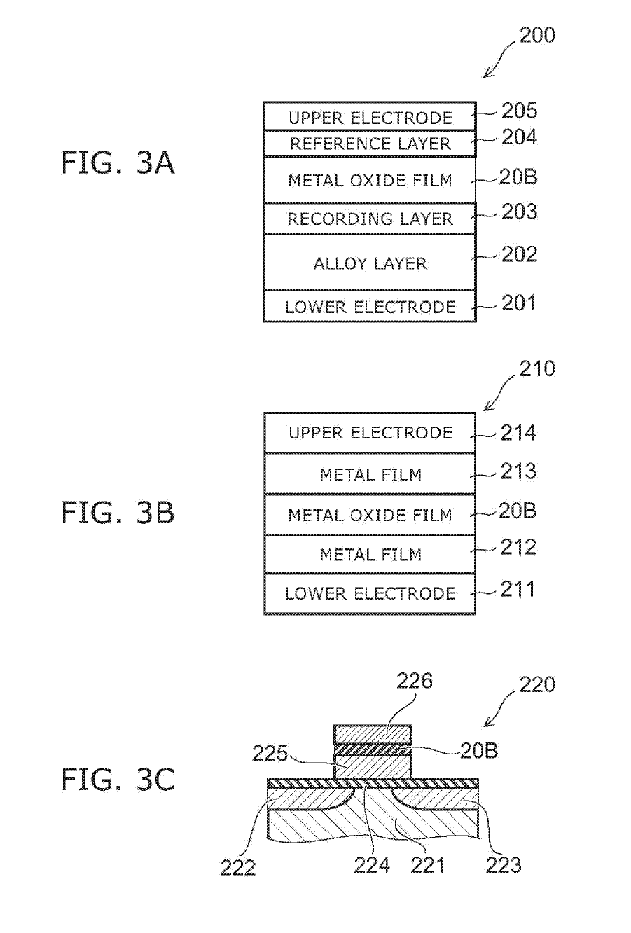

FIGS. 3A to 3C are schematic cross-sectional views for describing specific examples of the element.

First, FIG. 3A shows an overview of an MTJ (magnetic tunnel junction) element unit of a magnetoresistive memory (MRAM).

An MTJ element unit 200 has a stacked structure in which a lower electrode 201, an alloy layer 202, a recording layer 203, the metal oxide film 20B as a intermediate layer, a reference layer 204, and an upper electrode 205 are stacked in this order from bottom to top. The material of the recording layer 203 and the reference layer 204 is, for example, CoFeB. The material of the metal oxide film 20B is, for example, magnesium oxide (MgO).

Here, the state where the portion between the lower electrode 201 and the upper electrode 205 is low resistive is allotted to signal “1”. The state where the portion between the lower electrode 201 and the upper electrode 205 is high resistive is allotted to signal “0”. When signal “1” is read, the metal oxide film 20B is preferably as thin as possible in order to pass a tunnel current. On the other hand, when signal “0” is read, the metal oxide film 20B is preferably as high resistive as possible.

The MgO film formed by the embodiment has a density close to that of a MgO crystal and high insulating properties. Accordingly, the MgO film exhibits a high resistance value even if the MgO film is thinned.

If the density of the MgO film is low, in the case where the MgO film is thinned to 1 nm (nanometer) to 2 nm, the insulating properties of the MgO film are not sufficiently kept. In this case, in the MTJ element unit 200, the difference between the resistance in the state of signal “1” and the resistance in the state of signal “0” narrows, and it may be impossible to distinguish between “1” and “0”. As a method for enhancing the insulating properties of the ultrathin MgO film, the densifying modification of the MgO film by the irradiation with a cluster containing oxygen is effective.

FIG. 3B shows an overview of a memory unit of a resistance change memory (ReRAM).

A memory unit 210 of the resistance change memory has a stacked structure in which a lower electrode 211, a metal film 212, the metal oxide film 20B that is a recording layer, a metal film 213, and an upper electrode 214 are stacked in this order from bottom to top. Here, the material of the metal oxide film 20B is, for example, hafnium oxide (HfO₂).

Furthermore, other than HfO₂, at least one of TiO₂, ZrO₂, V₂O₅, Nb₂O₅, and Ta₂O₅ is possible. Furthermore, a film structure is also possible in which a film of one of the metal oxides mentioned above is stacked with a metal oxide film with a lower oxygen concentration than the film. For example, a stacked structure of metal oxides of the same kind and with different compositions may be used, such as TiO/TiO₂, ZrO/ZrO₂, VO/V₂O₅, NbO/Nb₂O₅, and TaO/Ta₂O₅.

By using a stacked structure of a metal oxide film with a high oxygen concentration and a metal oxide film with a low oxygen concentration as the metal oxide film 20B, oxygen can be moved to the film with a high oxygen concentration by applying a voltage to the stacked film. Thereby, the metal oxide film 20B is caused to include a metal oxide film having high insulating properties. Furthermore, if a reverse voltage in which positive and negative are reversed is applied to the stacked film, oxygen moves to the film with a low oxygen concentration to reduce the insulating properties of the metal oxide film 20B. Thereby, the repeatability of the resistance change of the metal oxide film 20B is improved.

In the memory unit 210 of the resistance change memory, the voltage applied between the major surfaces of the metal oxide film 20B that is a resistance change film changes with the combination of the electric potentials given to the lower electrode 211 and the upper electrode 214. By means of the resistance value of the metal oxide film 20B, the information of “1” or “0” can be recorded, stored, and erased.

The HfO₂ film formed by the embodiment has a density close to that of a HfO₂ crystal and high insulating properties. If the density of the HfO₂ film is low, the insulating properties of the HfO₂ film cannot be sufficiently kept when the HfO₂ film is thinned. In this case, in the memory unit 210, the difference between the resistance in the state of signal “1” and the resistance in the state of signal “0” narrows, and it may be impossible to distinguish between “1” and “0”. As a method for enhancing the insulating properties of the ultrathin HfO₂ film, the densifying modification of the HfO₂ film by the irradiation with a cluster containing oxygen is effective.

FIG. 3C shows a gate electrode unit of a flash memory.

A flash memory 220 includes a base region 221, a source region 222 and a drain region 223 selectively provided on the surface of the base region 221. Furthermore, the flash memory 220 includes a gate insulating film 224 provided on the base region 221, the source region 222, the drain region 223, a floating gate 225 provided on the gate insulating film 224, the metal oxide film 20B that is a dielectric layer provided on the floating gate 225, and a control gate 226 provided on the metal oxide film 20B. The material of the metal oxide film 20B is, for example, hafnium oxide (HfO₂), aluminum oxide (Al₂O₃), or the like.

First, a voltage not less than the threshold voltage is applied to the control gate 226 to pass a current from the source region 222 to the drain region 223. Electrons that have obtained a high energy in the drain region 223 become hot electrons or a tunnel current, and part of them pass through the gate insulating film 224 to enter the floating gate 225. In the case where the floating gate 225 is electrically charged, the enhancement type is obtained in which no current flows between source and drain when the control gate 226 is 0 (V). In the case where the floating gate 225 is not electrically charged, the depression type is obtained in which a current flows between source and drain even when the control gate 226 is 0 (V).

When charging the floating gate 225 with electrons, the metal oxide film 20B is preferably as thin as possible. On the other hand, to retain the electrostatic charge of the floating gate 225, the metal oxide film 20B is preferably as high resistive as possible.

The HfO₂ film (or the Al₂O₃ film or the LaAlO film) formed by the embodiment has a density close to that of a HfO₂ crystal (or an Al₂O₃ crystal or a LaAlO crystal) and high insulating properties. If the density of the HfO₂ film (or the Al₂O₃ film or the LaAlO film) is low, the insulating properties of the HfO₂ film (or the Al₂O₃ film or the LaAlO film) are not sufficiently kept when the HfO₂ film (or the Al₂O₃ film or the LaAlO film) is thinned. In this case, the electrostatic charge of the floating gate 225 is insufficient, and it may be impossible to distinguish between the “1” and “0” signals of the flash memory. As a method for enhancing the insulating properties of the ultrathin HfO₂ film (or the Al₂O₃ film or the LaAlO film), the densifying modification of the HfO₂ film (or the Al₂O₃ film or the LaAlO film) by the irradiation with a cluster containing oxygen is effective.

Here, the floating gate 225 is an example in this embodiment. The floating gate 225 can be exchanged with a charge storage layer. The charge storage layer has a MONOS (Metal Oxide Nitride Oxide Silicon) structure. The MONOS structure is a stacked body structure which includes a metal oxide film/a metal oxynitride film/a metal nitride film.

Thus, it is effective to incorporate the metal oxide film 20B formed by the film formation method of the embodiment into the MTJ element unit 200 of the resistance change memory, the memory unit 210 of the resistance change memory, or the gate electrode unit of the flash memory.

### Second Embodiment

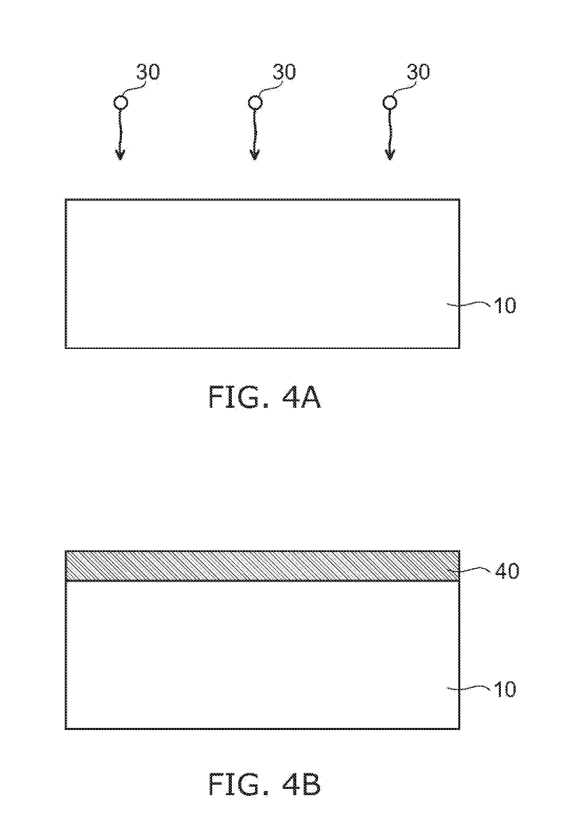

FIGS. 4A and 4B are schematic film cross-sectional views for describing a film formation method according to a second embodiment.

In the film formation method according to the second embodiment, as shown in FIG. 4A, gas cluster ions 30 containing a metal element are applied onto the underlayer 10. Then, as shown in FIG. 4B, a metal film 40 containing the metal element is formed on the underlayer 10. In the second embodiment, since the metal film 40 is deposited using the gas cluster ions 30, a compact and highly pure metal film 40 is formed on the underlayer 10. Furthermore, since the metal film 40 is formed while the surface of the underlayer 10 is irradiated with the gas cluster ions 30, a metal film 40 excellent in the adhesion to the underlayer 10 is formed on the underlayer 10. In this case, a metal film 40 excellent in the adhesion to the underlayer 10 is formed on the underlayer 10 regardless of the material of the underlayer 10. For example, even if the material of the underlayer 10 is a semiconductor or an insulator (SiO₂, Si₃N₄, etc.), a metal film 40 excellent in the adhesion to the underlayer 10 is formed on the underlayer 10. The metal film 40 is used as, for example, an electrode of semiconductor elements, magnetic elements, and the like.

Vaporized magnesium chloride (MgCl₂) gas, for example, is used as the gas cluster ions 30. The concentration of the magnesium chloride gas may be reduced with hydrogen (H₂) gas. The magnesium chloride (MgCl₂) and the hydrogen (H₂) are put in the gas supply mechanism 107 of the film formation apparatus 100. In the second embodiment, oxygen (O₂), argon (Ar), hydrogen (H₂), and the like may be put in the gas pressurization mechanism 102 as necessary.

In the film formation method according to the second embodiment, gas cluster ions 30 containing magnesium chloride gas are generated in the film formation apparatus 100 and applied onto the underlayer 10. The number of atoms contained in the gas cluster ions 30 is, for example, not less than 2,000 and not more than 5,000.

When the gas cluster ions 30 are applied onto the underlayer 10, the temperature of the surface of the underlayer 10 irradiated with the gas cluster ions 30 (a portion of the surface of the underlayer 10 with a diameter approximately equal to that of the gas cluster ions 30) increases locally to approximately 10,000 degrees C. in a picosecond (10⁻¹² second). In addition, the local portion of the surface receives the kinetic energy of the gas cluster ions 30.

Thereby, the MgCl₂ is decomposed, and the magnesium (Mg) in the gas cluster ions 30 is selectively deposited on the underlayer 10. The components (Cl, H, etc.) other than magnesium (Mg) are vaporized at the local portion of the surface and efficiently discharged via the exhaust port 105. The magnesium film formed on the underlayer 10 has a film thickness of about 1 nm to 10 nm. If such a magnesium film is deposited on a Si substrate, the Si substrate reacts with the Mg film to form a Mg₂Si film at the interface between the magnesium film and the Si substrate. The Schottky barrier heights between the magnesium film and p-type Si and between the magnesium film and n-type Si are 0.7 eV and 0.45 eV, respectively.

In the second embodiment, since the underlayer 10 is irradiated with the gas cluster ions 30 to form the metal film 40 on the underlayer 10, the migration of metal atoms on the underlayer 10 (a phenomenon in which components in the metal film move on the underlayer) is promoted. Consequently, the metal film 40 formed on the underlayer 10 becomes a compact film as compared to metal films formed by the sputtering method, ALD, and CVD.

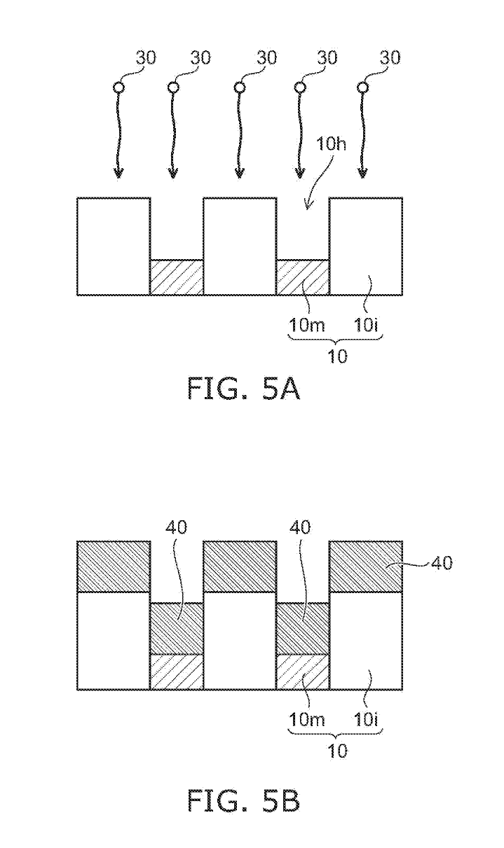

FIGS. 5A and 5B are schematic film cross-sectional views for describing a modification example of the film formation method according to the second embodiment.

As shown in FIG. 5A, via holes 10h are provided from the surface to the interior of the underlayer 10. Gas cluster ions 30 containing a metal element are applied onto the underlayer 10 in which the via holes 10h are provided. The underlayer 10 includes an insulating layer 10i and a metal layer 10m. Then, as shown in FIG. 5B, a metal film 40 containing the metal element is formed on the bottom surface in the via hole 10h and the surface of the underlayer 10 outside the via hole 10h. The metal film 40 formed in the via hole 10h is used as, for example, a contact plug electrode of semiconductor elements and magnetic elements. The metal film 40 may be referred to as a metal layer.

In this modification example, a mixed gas of tungsten hexafluoride (WF₆) and silane (SiH₄), for example, is used as the gas cluster ions 30. The number of atoms contained in the gas cluster ions 30 is, for example, not less than 2,000 and not more than 5,000.

The gas cluster ions 30 are accelerated in the film formation apparatus 100 by the acceleration mechanism 103 in the direction from the nozzle portion 102n to the substrate support stand 104. Therefore, gas cluster ions 30 moving in the depth direction of the via hole 10h are predominant. Thereby, part of the gas cluster ions 30 reach the inner side surface of the via hole 10h and most of the gas cluster ions 30 easily reach the bottom surface of the via hole 10h.

When the bottom surface of the via hole 10h is irradiated with the gas cluster ions 30, the temperature of the bottom surface of the via hole 10h irradiated with the gas cluster ions 30 (a portion of the bottom surface with a diameter approximately equal to that of the gas cluster ions 30) increases locally to approximately 10,000 degrees C. in a picosecond (10⁻¹² second). In addition, the local portion of the bottom surface receives the kinetic energy of the gas cluster ions 30. Thereby, the WF₆ is decomposed, and the tungsten (W) in the gas cluster ions 30 is preferentially deposited from the bottom surface of the via hole 10h.

In the embodiment, since the tungsten film (W film) is formed while the bottom surface and the inner side surface of the via hole 10h are irradiated with the gas cluster ions 30, a compact tungsten film (W film) is formed in the via hole 10h. Furthermore, the adhesion between the tungsten film (W film) and the underlayer 10 is good.

Furthermore, since the temperature of the bottom surface of the via hole 10h increases to approximately 10,000 degrees C. in a picosecond (10⁻¹² second), the components (Si, H, F, etc.) other than tungsten (W) are immediately vaporized away to the exterior of the via hole 10h with ease. Thereby, the components (Si, H, F, etc.) other than tungsten (W) are efficiently discharged via the exhaust port 105. Therefore, a compact tungsten film is formed and the purity of the tungsten film is high.

In the ordinary selective tungsten CVD method, since the adhesion between the tungsten film (W film) and the underlayer 10 in the via hole 10h is insufficient, it is necessary to interpose a barrier film such as a tungsten silicide film (WSiₓ film) and a titanium-based film (Ti film or TiN film) between the tungsten film (W film) and the underlayer 10. However, since such a barrier film has a relatively high resistivity, the resistance may increase as the whole contact plug electrode. Furthermore, in the ordinary selective tungsten CVD method, since the temperature of the bottom surface of the via hole 10h does not increase so much as in the embodiment, it is difficult for the components (Si, H, F, etc.) other than tungsten (W) to be vaporized away to the exterior of the via hole 10h. As a result, Si, H, F, and the like may be mixed into the tungsten film.

In the embodiment, there is no need to provide the barrier film described above, and the tungsten film (W film) is directly in contact with the bottom surface and the side surface of the via hole 10h.

The surplus metal film 40 formed on the surface of the underlayer 10 other than the via hole 10h may be removed by, for example, CMP (chemical mechanical polishing) or the like. The metal film 40 may be formed in a trench provided from the surface to the interior of the underlayer 10 in place of the via hole 10h.

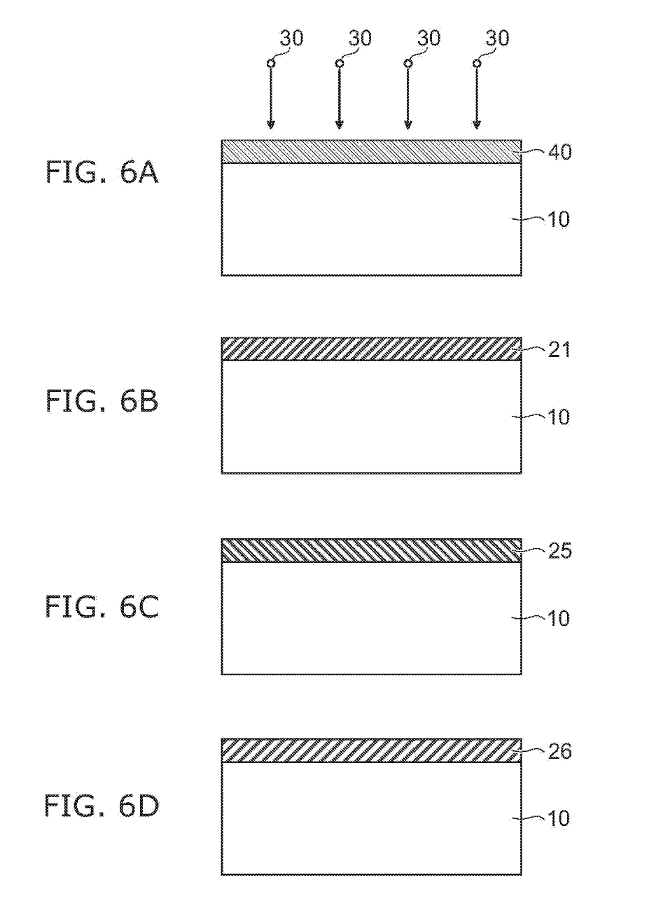

FIGS. 6A to 6D are schematic film cross-sectional views for describing another modification example of the film formation method according to the second embodiment.

As shown in FIG. 6A, the metal film 40 is formed on the underlayer 10 beforehand. The metal film 40 is formed by the method shown in FIGS. 4A and 4B. Next, the surface of the metal film 40 formed on the underlayer 10 is irradiated with gas cluster ions 30 containing oxygen (O) to change at least part of the metal film 40 into a metal oxide film 21 containing a metal element in the metal film 40. The metal oxide film 21 has a film thickness of, for example, 0.5 nm to 10 nm. This state is shown in FIG. 6B.

For example, a magnesium film (Mg film) is formed on the underlayer 10 as the metal film 40, and then the magnesium film (Mg film) is irradiated with gas cluster ions 30 containing oxygen (O) to change the magnesium film (Mg film) into a magnesium oxide film (MgO film). Alternatively, in place of the magnesium film (Mg film), any one of a hafnium film (Hf film), an aluminum film (Al film), a lanthanum film (La film), a cerium film (Ce film), and a film of another rare earth metal may be irradiated with the gas cluster ions 30 to form a hafnium oxide film (HfO₂ film), an aluminum oxide film (Al₂O₃ film), a lanthanum oxide film (La₂O₃ film), a cerium oxide film (CeO₂ film), or an oxide film of the other rare earth metal on the underlayer 10. Any one of a hafnium film (Hf film), an aluminum film (Al film), a lanthanum film (La film), a cerium film (Ce film), and a film of another rare earth metal is formed on the underlayer 10 using the gas cluster ions 30.

The amount of the decrease in the Gibbs free energy when the metal film 40 of aluminum (Al), lanthanum (La), hafnium (Hf), cerium (Ce), another rare earth metal, or the like changes into the metal oxide film 21 is larger than the amount of the decrease in the Gibbs free energy when silicon (Si) changes into silicon oxide (SiO₂). In the case where the underlayer 10 is silicon (Si), even such a metal film is not reduced by silicon (Si) and a compact metal oxide film 21 is formed.

If a magnesium film (Mg film) is deposited on a CoFeB film and then the magnesium film is irradiated with an oxygen cluster, a highly pure magnesium oxide film (MgO film) is formed. The MgO film formed has good crystal orientation properties. In addition, a CoFeB film formed on the MgO film and the CoFeB film under the MgO film may be heated at 350 degrees C. or less in a state where a layer containing tantalum (Ta), niobium (Nb), vanadium (V), titanium (Ti), zirconium (Zr), hafnium (Hf), or a rare earth metal, which easily bonds to boron (B), exists in the metal layers or the alloy layers adjacent to the respective CoFeB layers or therearound. Thereby, the CoFeB layers become magnetic films having good orientation properties.

The advantage of forming the metal oxide film 21 using the gas cluster ions 30 is as described in regard to the metal oxide film 20B of the first embodiment. That is, it is effective to incorporate the metal oxide film 21 into the MTJ element unit 200 of the magnetoresistive memory, the memory unit 210 of the resistance change memory, or the gate electrode unit of the flash memory.

Alternatively, the surface of the metal film 40 provided on the underlayer 10 may be irradiated with gas cluster ions 30 containing nitrogen (N) to change at least part of the metal film 40 into a metal nitride film 25 containing a metal element in the metal film 40, as shown in FIG. 6C. Thereby, a compact metal nitride film 25 is formed on the underlayer 10. Furthermore, the surface of the metal film 40 provided on the underlayer 10 may be irradiated with gas cluster ions 30 containing oxygen (O) and nitrogen (N) to change at least part of the metal film 40 into a metal oxynitride film 26 containing a metal element in the metal film 40, as shown in FIG. 6D. Thereby, a compact metal oxynitride film 26 is formed on the underlayer 10.

### Third Embodiment

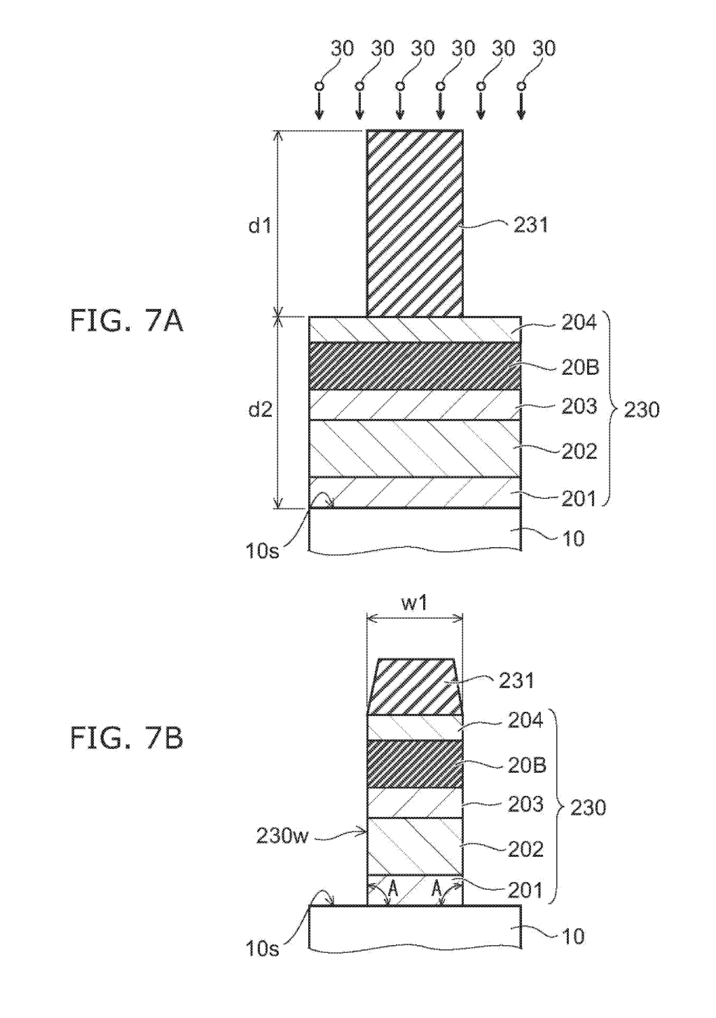

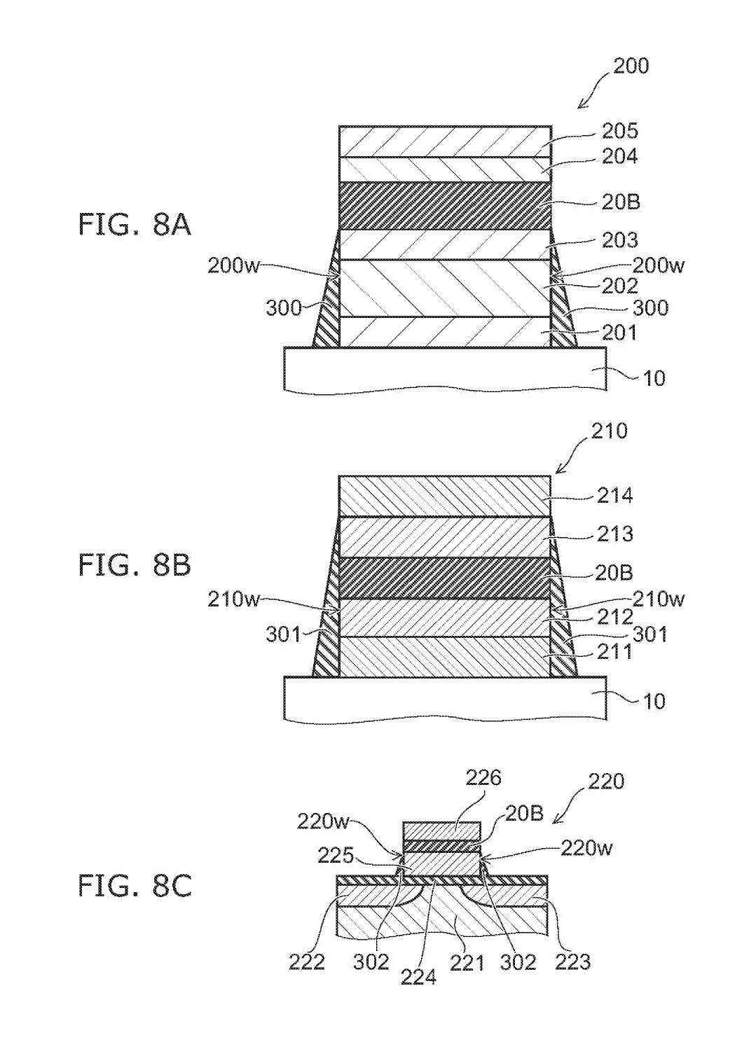

FIGS. 7A and 7B are schematic film cross-sectional views for describing a film formation method according to a third embodiment.

In the film formation method according to the third embodiment, as shown in FIG. 7A, a layer to be processed 230 provided on the underlayer 10 is selectively irradiated with gas cluster ions 30 containing at least one of carbon dioxide (CO₂) and a halogen element. Then, as shown in FIG. 7B, the portion of the layer to be processed 230 selectively irradiated with the gas cluster ions 30 is selectively removed.

An MTJ element unit is shown as an example of the layer to be processed 230. The layer to be processed 230 includes at least one of a metal film and a metal oxide film. In addition to this, the layer to be processed 230 may be the memory unit of the resistance change memory shown in FIG. 3B. Alternatively, the layer to be processed 230 may be the gate electrode unit of the flash memory shown in FIG. 3C. In this case, the layer to be processed 230 includes an insulating film (the gate insulating film 224) and conductive layers (the floating gate 225 and the control gate 226).

The layer to be processed 230 shown in FIG. 7A has, for example, a stacked structure in which the lower electrode 201, the alloy layer 202, the recording layer 203, the metal oxide film 20B as a intermediate layer, and the reference layer 204 are stacked in this order from the underlayer 10 side. A hard mask 231 is selectively provided on the layer to be processed 230. The hard mask 231 is, for example, a stacked body of a silicon oxide film (SiO₂ film) and a tantalum film (Ta film), a ruthenium film (Ru film), or a stacked body of a ruthenium film (Ru film) and a silicon oxide film (SiO₂ film). It is also possible to use a metal having a higher electronegativity than iron (Fe), cobalt (Co), and nickel (Ni), such as platinum (Pt), palladium (Pd), rhodium (Rh), and iridium (Ir), in place of ruthenium (Ru). Also in this case, similar effects can be obtained. The hard mask 231 has a thickness of d1 and the layer to be processed 230 has a thickness of d2 before the layer to be processed 230 is irradiated with the gas cluster ions 30. In the embodiment, the thickness of the hard mask 231 is adjusted so that d1 may be thicker than d2.

Subsequently, the layer to be processed 230 is selectively irradiated with gas cluster ions 30 containing at least one of carbon dioxide (CO₂) and a halogen element (e.g. chlorine (Cl₂)). The number of atoms contained in the gas cluster ions 30 is not less than 100 and not more than 20,000. The number of atoms contained in the gas cluster ions 30 is preferably not less than 1,000 and not more than 10,000.

The gas cluster ions 30 are accelerated in the film formation apparatus 100 by the acceleration mechanism 103 in the direction from the nozzle portion 102n to the substrate support stand 104. Thereby, gas cluster ions 30 moving in the direction perpendicular to the surface 10s of the underlayer 10 are predominant, and the gas cluster ions 30 are incident substantially perpendicularly to the major surface of the layer to be processed 230.

When the surface of the layer to be processed 230 is irradiated with the gas cluster ions 30, the temperature of the surface of the layer to be processed 230 irradiated with the gas cluster ions 30 (a portion of the surface of the layer to be processed 230 with a diameter approximately equal to that of the gas cluster ions 30) increases locally to approximately 10,000 degrees C. in one to ten picoseconds (10⁻¹² second). In addition, the local portion of the surface receives the kinetic energy of the gas duster ions 30. Thereby, chemical and physical etching proceeds at the surface of the layer to be processed 230.

In the case where the thickness of each layer of the layer to be processed 230 is several nanometers or less and the thickness of the layer to be processed 230 is 30nm or less before processing, the angle A between the side surface 230w of the layer to be processed 230 and the surface 10s of the underlayer 10 becomes 80 degrees to 90 degrees after the layer to be processed 230 is irradiated with the gas cluster ions 30. Furthermore, the width W1 in a direction parallel to the surface 10s of the underlayer 10 becomes 15 nm to 40 nm after processing. Since the hard mask 231 is configured to be thicker than the layer to be processed 230 beforehand, part of the hard mask 231 remains after etching.

In the film formation method according to the third embodiment, there is little damage to the side surface 230w of the layer to be processed 230 and an unnecessary side wall deposition film is less easily formed on the side surface 230w of the layer to be processed 230.

For example, in the case where an unnecessary side wall deposition film is formed on the side surface 230w of the layer to be processed 230, the following malfunctions are caused. The unnecessary side wall deposition film may be formed by ordinary RIE (reactive ion etching), ion trimming, and the like.

FIGS. 8A to 8C are views for describing examples in which a side wall deposition film is formed on the side surface of the layer to be processed after processing.

For example, FIG. 8A shows a state where an unnecessary side wall deposition film 300 is formed on the side surface 200w of the MTJ element unit 200 of the magnetoresistive memory. The side wall deposition film 300 is in contact with, for example, the recording layer 203, the alloy layer 202, and the lower electrode 201. In this case, if the unnecessary side wall deposition film 300 has magnetism and/or electrical conductivity, the MTJ element unit 200 may not function as the memory unit of the magnetoresistive memory. A contact layer or the like provided on a semiconductor layer, for example, corresponds to the underlayer 10.

FIG. 8B shows a state where an unnecessary side wall deposition film 301 is formed on the side surface 210w of the memory unit 210 of the resistance change memory. The side wall deposition film 301 is in contact with, for example, the metal film 213, the metal oxide film 20B, the metal film 212, and the lower electrode 211. In this case, if the unnecessary side wall deposition film 301 has electrical conductivity, the recording unit 210 may not function as the memory unit of the resistance change memory. A contact layer or the like provided on a semiconductor layer, for example, corresponds to the underlayer 10.

FIG. 8C shows a state where an unnecessary side wall deposition film 302 is formed on the side surface 220w of the gate electrode unit of the flash memory 220. In this case, when the source region 222 and the drain region 223 are formed by ion implantation, the side wall deposition film 302 forms a shield layer to possibly prevent the source region 222 and the drain region 223 from being formed immediately below the control gate 226. As a consequence, the channel layer formed in the base region 221 immediately below the control gate 226 may not be connected to the source region 222 and the drain region 223, and this may cause an operational malfunction of the flash memory 220.

In contrast, in the film formation method according to the third embodiment, since the layer to be processed 230 is processed using the gas duster ions 30, the side wall deposition films 300, 301, and 302 are less easily formed.

In the film formation method according to the third embodiment, the acceleration energy of the gas cluster ions 30 applied to the layer to be processed 230 may be changed in two steps in order to suppress the damage to the surface of the layer to be processed 230. For example, at the initial processing stage, the gas cluster ions 30 are accelerated with 20 keV or more. Subsequently, at the final stage of processing, the gas cluster ions 30 are accelerated with 10 keV or less. Alternatively, the gas cluster ions 30 may be accelerated with 10 keV or less from the beginning. Thus, by weakening the acceleration energy of the gas cluster ions 30, the surface of the layer to be processed 230 finally processed becomes smoother. In this way, in the third embodiment, the layer to be processed is included in the nonvolatile memory device. The layer to be processed is included in the magnetoresistive memory, the layer is sandwiched between the lower electrode and the upper electrode, and the layer includes an alloy layer, a recording layer, intermediate layer, and a reference layer. The layer to be processed is included in the resistance change memory, the layer is sandwiched between a lower electrode and an upper electrode, and the layer includes a first metal layer, a resistance change film, and a second metal layer. The layer to be processed is included in the flash memory, and the layer includes the dielectric layer, a charge storage layer, and a control gate.

### Fourth Embodiment

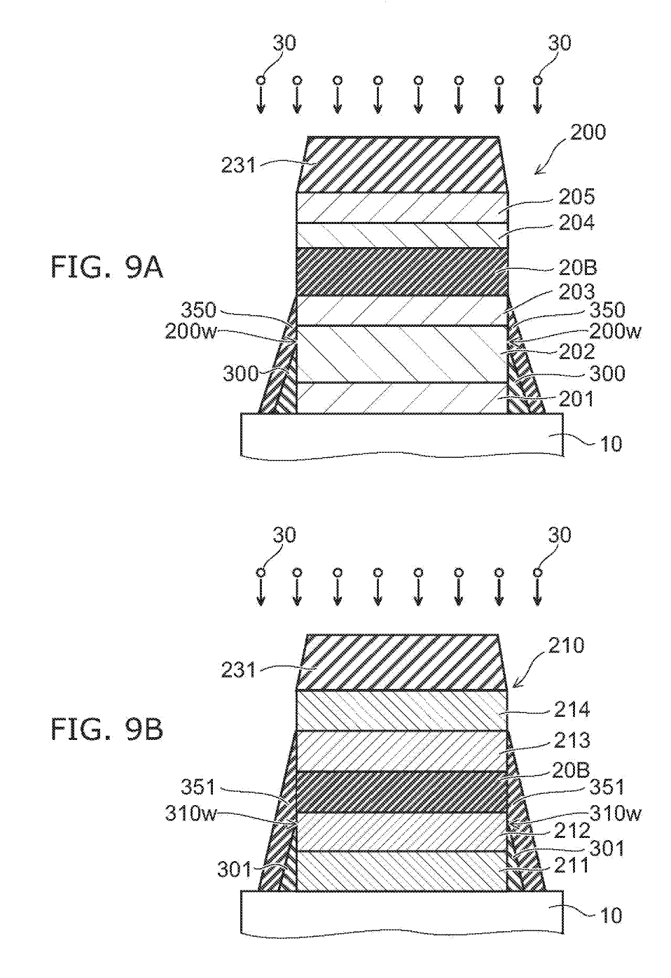

FIGS. 9A and 9B are schematic film cross-sectional views for describing a film formation method according to a fourth embodiment.

In the film formation method according to the fourth embodiment, as shown in FIG. 9A, in the case where the unnecessary side wall deposition film 300 is formed on the side surface of the MTJ element unit 200 of the magnetoresistive memory, the side wall deposition film 300 is irradiated with gas duster ions 30 containing at least one of oxygen (O) and nitrogen (N) to change at least part of the side wall deposition film 300 into a modified layer 350. The modified layer 350 is any one of a metal oxide film, a metal nitride film, and a metal oxynitride film. In other words, the modified layer 350 is a layer having neither magnetism nor electrical conductivity.

FIG. 9A shows a state where the modified layer 350 is formed on the surface of the side wall deposition film 300. The modified layer 350 is in contact with the recording layer 203 and the alloy layer 202 of the MTJ element unit 200.

Thus, by changing at least part of the essentially unnecessary side wall deposition film 300 into the modified layer 350 having neither magnetism nor electrical conductivity, the MTJ element unit 200 is less easily affected by the magnetic and electrical properties of the side wall deposition film 300. Thereby, an MTJ element unit 200 having a desired function is formed.

Furthermore, as shown in FIG. 9B, in the case where the unnecessary side wall deposition film 301 is formed on the side surface of the memory unit 210 of the resistance change memory, the side wall deposition film 301 is irradiated with gas cluster ions 30 containing at least one of oxygen (O) and nitrogen (N) to change at least part of the side wall deposition film 301 into a modified layer 351. The modified layer 351 is any one of a metal oxide film, a metal nitride film, and a metal oxynitride film. In other words, the modified layer 351 is a layer having no electrical conductivity.

FIG. 9B shows a state where the modified layer 351 is formed on the surface of the side wall deposition film 301. The modified layer 351 is in contact with the metal film 213, the metal oxide film 20B that is a recording layer, the metal film 212, and the lower electrode 211 of the memory unit 210 of the resistance change memory.

Thus, by changing at least part of the essentially unnecessary side wall deposition film 301 into the modified layer 351 having no electrical conductivity, the memory unit 210 is less easily affected by the electrical properties of the side wall deposition film 301. Thereby, a memory unit 210 having a desired function is formed.

Atoms of at least one of oxygen (O) and nitrogen (N), the number of which is not less than 100 and not more than 20,000, are contained in the gas cluster ions 30 when the modified layers 350 and 351 are formed. The energy per atom in the gas cluster ions 30 is not less than 1 eV and not more than 30 eV. The modified layers 350 and 351 have a film thickness of, for example, 10 nm or less.

### Fifth Embodiment

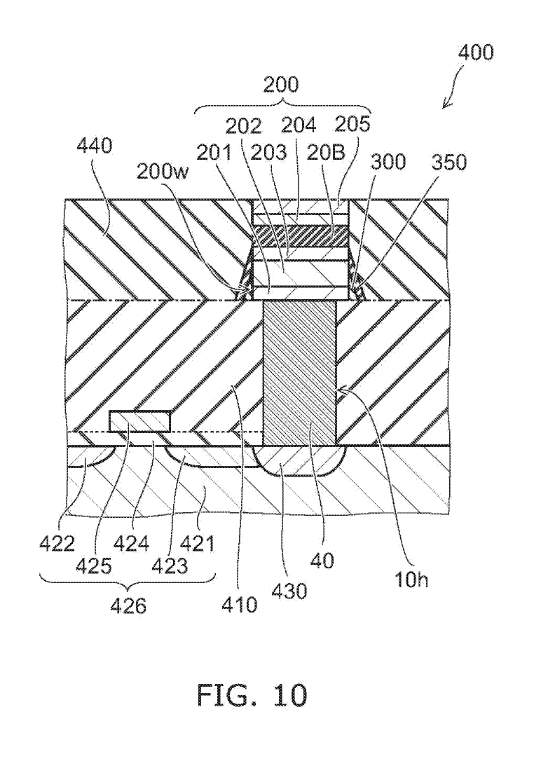

FIG. 10 is an element cross-sectional view according to a fifth embodiment.

FIG. 10 shows a main part of a nonvolatile memory device 400 including the MTJ element unit 200. The MTJ element unit 200 is a rewritable nonvolatile memory cell. The metal film 40 as an interconnection layer (contact via) is electrically connected to the lower electrode 201 of the MTJ element unit 200. The metal film 40 is, for example, the tungsten film (W film) illustrated in the second embodiment. The metal film 40 is provided in the via hole 10h provided in an insulating layer 410 that is an interlayer insulating film. No barrier layer is provided between the metal film 40 and the insulating layer 410. That is, since the adhesion between the metal film 40 and the insulating layer 410 is good, there is no need to provide a barrier layer. The metal film 40 is directly in contact with the insulating layer 410 in the via hole 10h.

The insulating layer 410 is provided on a base region 421 that is a semiconductor layer (semiconductor substrate). A source region 422 and a drain region 423 are selectively provided on the surface of the base region 421. A gate electrode 425 is provided above the base region 421 between the source region 422 and the drain region 423 via a gate insulating film 424. The drain region 423 is connected to the metal film 40 via a contact layer 430 provided on the surface of the base region 421. That is, the MTJ element unit 200 is connected to a switching element 426 of a MOS structure via the metal film 40. An insulating layer 440 that is an interlayer insulating film is provided on the insulating layer 410.

The unnecessary side wall deposition film 300 is formed on the side surface 200w of the MTJ element unit 200. However, the surface of the side wall deposition film 300 has been changed into the modified layer 350. If the MTJ element unit 200 is formed like the third embodiment, the side wall deposition film 300 is not formed. That is, also a configuration in which the side wall deposition film 300 and the modified layer 350 are removed from the configuration of FIG. 10 is included in the embodiment.

In the embodiment, in addition to the metal oxide films described above, also a semiconductor oxide film, a semiconductor nitride film, or a semiconductor oxynitride film may be irradiated with gas cluster ions 30 containing oxygen, nitrogen, and/or the like; thereby, the density thereof can be increased. For example, a silicon oxide film (SiO₂ film) and a silicon oxynitride film (SiON film) may be irradiated with gas cluster ions 30 containing oxygen and the like; thereby, the density thereof can be increased. Alternatively, a silicon nitride film (Si₃N₄ film) may be irradiated with gas cluster ions 30 containing nitrogen and the like; thereby, the density thereof can be increased.

The amount of the decrease in the Gibbs free energy when a metal film formed of a metal contained in the metal oxide film 20 changes into the metal oxide film 20 is larger than the amount of the decrease in the Gibbs free energy when silicon (Si) changes into silicon oxide (SiO₂). Thus, the film formation method according to the embodiment is effective in increasing the density of a metal oxide that is more thermally stable than silicon oxide (SiO₂), improving the insulating properties thereof, and performing microfabrication thereof.

Hereinabove, embodiments are described with reference to specific examples. However, the embodiments are not limited to these specific examples. One skilled in the art may appropriately make design changes to these specific examples, and such modifications also are included in the scope of the embodiments to the extent that the spirit of the embodiments is included. The components of the specific examples described above and the arrangement, material, conditions, shape, size, and the like thereof are not limited to those illustrated but may be appropriately altered.

Furthermore, the components of the embodiments described above may be combined within the extent of technical feasibility, and combinations of them also are included in the scope of the embodiments to the extent that the spirit of the embodiments is included. Furthermore, one skilled in the art may arrive at various alterations and modifications within the idea of the embodiments. Such alterations and modifications should be seen as within the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

1-20. (canceled)

21. A film formation method comprising:
forming a film structure including a first metal contained film on a substrate;
processing the film structure to form a pattern of the film structure and a side wall on the substrate, the side wall contacting with a side surface of the first metal contained film in the pattern of the film structure; and
irradiating gas cluster ions into the side wall on the substrate.

22. The method according to claim 21, wherein
the film structure includes a second metal contained film, and the side wall contacts with the second metal contained film.

23. The method according to claim 21, wherein
the side wall where the gas cluster ions are irradiated is an insulating film.

24. The method according to claim 21, wherein
the gas cluster ions include nitrogen.

25. The method according to claim 21, wherein
the gas cluster ions include oxygen.

26. The method according to claim 21, wherein
the side wall is modified by irradiating the gas cluster ions into the side wall.

27. The method according to claim 21, wherein
an electrical insulation property of the side wall is improved by irradiating the gas cluster ions into the side wall.

28. The method according to claim 21, wherein
a number of atoms contained in the gas cluster ions is not less than 100 and not more than 20,000.

29. The method according to claim 21, wherein
a kinetic energy per atom contained in the gas cluster ions immediately before the irradiation is not less than 1 eV and not more than 30 eV.

30. The method according to claim 21, wherein
the first metal contained film is a lower electrode, the second metal contained film is an upper electrode in a memory unit of a resistance change memory.

31. The method according to claim 22, wherein
the pattern of the film structure further includes a metal oxide film between the first metal contained film and the second metal contained film.

32. The method according to claim 21, wherein
the pattern of the film structure includes a memory cell.

33. The method according to claim 22, wherein
the memory cell is a MTJ element unit of a resistance change memory or a memory unit of a resistance change memory,
the MTJ element unit including:
a lower electrode;
an alloy layer provided on the lower electrode;
a recording layer provided on the alloy layer, the recording layer including CoFeB;
a metal oxide film provided on the recording layer, the metal oxide film including MgO; and
a reference layer including CoFeB, or
the memory unit including:
a lower electrode;
a metal oxide film provided on lower electrode, the metal oxide film including at least one of MgO, TiO₂, ZrO₂, V₂O₅, Nb₂O₅, Ta₂O₅, TiO₂, ZrO, VO, NbO, and TaO; and
an upper electrode provided on the metal oxide film.

34. The method according to claim 21, wherein
the film structure is processed by reactive ion etching to form the pattern of the film structure.

35. A memory device comprising:
a substrate;
a memory cell including a first metal contained film on a substrate; and
a side wall contacting with a side surface of the first metal contained film, and the side wall being irradiated by gas cluster ions.

36. The device according to claim 35, wherein
the memory cell includes a second metal contained film, and the side wall contacts with the second metal contained film.

37. The device according to claim 35, wherein
the side wall where the gas cluster ions are irradiated is an insulating film.

38. The device according to claim 35, wherein
the gas cluster ions include at least one of nitrogen and oxygen.

39. The device according to claim 36, wherein
the memory cell further includes a metal oxide film between the first metal contained film and the second metal contained film.

40. The device according to claim 35, further comprising:
a metal film electrically connected to the first metal contained film.
